(19) United States
(12) Patent Application Publication
(10) Pub. No.: US 2007/0017686 A1
(43) Pub. Date: Jan. 25, 2007

(54) Electronic apparatus, and heat sink incorporated in the electronic apparatus

(76) Inventor: Takehiko Numata, Hidaka-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/476,783

(22) Filed: Jun. 29, 2006

(30) Foreign Application Priority Data
Jun. 30, 2005 (JP) 2005-193060

(51) Int. Cl. H05K 5/00

(52) U.S. Cl. 174/17 VA

(57) ABSTRACT

According to one embodiment, the heat sink secured to the LSI mounted on the circuit board of an electronic apparatus has radiating plates extended substantially parallel to the circuit board, and radiating fins extended from the radiating plate to the circuit board. The radiating fins are made short to ensure space to mount other circuit components and 38 mounted on the circuit board.

### CROSS-REFERENCE TO RELATED APPLICATIONS

This application is based upon and claims the benefit of priority from Japanese Patent Application No. 2005-193060, filed Jun. 30, 2005, the entire contents of which are incorporated herein by reference.

### BACKGROUND

1. Field

One embodiment of the invention relates to an electronic apparatus such as a digital broadcast receiver to receive digital television broadcasting, and more particularly an electronic apparatus characterized by the structure of a heat sink secured to a heat-generating circuit component.

2. Description of the Related Art

Digitalization of television broadcasting has been promoted in recent years. For example, digital terrestrial broadcasting began, as well as BS (Broadcasting Satellite) digital broadcasting and 110° CS (Communication Satellite) digital broadcasting.

In a digital broadcasting receiver to receive such digital television broadcasting, high-speed processing of digital video data is especially demanded, and a circuit component such as LSI (Large Scale Integration) to execute the high-speed processing generates a relatively large heating value. Therefore, it is important to take sufficient heat-radiating measure for such a heat-generating circuit component.

As a heat-radiating structure of a circuit component, a heat sink secured to a circuit component through a heat-conducting sheet is generally known. A heat sink is made of metal material with good heat conduction, and has radiating fins. To obtain sufficient radiating effect for a circuit component generating a relatively large heating value, as described above, it is necessary to provide a relatively large heat sink. However, if a large heat sink is secured to a specific circuit component, another component cannot be provided at the position overlapping the heat sink, and the size of the apparatus becomes large. Particularly, it is difficult to take space to provide a circuit component such as a chemical condenser difficult to reduce the size.

Further, a circuit component generating a relatively small heating value is provided close to a heat sink, the heat of a circuit component generating a large heating value may be transmitted to the circuit component generating a small heating value through the heat sink. In this case, while the heat of a circuit component provided with a heat sink can be efficiently radiated, other circuit components arranged around that component are undesirably heated.

As a solution of the above problem, there is a known heat-radiating structure, in which circuit components with different heating values are put in cavities 20a of an aluminum die casting base 20, radiating fins 20b are provided opposite to the cavities 20a, resin material with high heat conductivity is filled in the cavity containing a circuit component generating a relatively large heating value, and resin material with heat insulation is filled in the cavity containing a circuit component generating a relatively small heating value. It is disclosed by, for example, US005373418A (FIG. 1).

By using the above heat-radiating structure, the heat of a circuit component with a large heating value can be efficiently radiated, and the conduction of the heat to a circuit component with a small heating value can be prevented. But, even if this heat-radiating structure is used, it is unavoidable to increase the size of an electronic apparatus using this structure.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram of a video signal processing circuit of a television broadcasting receiver according to an embodiment of an electronic apparatus of the invention;

FIG. 2 is an exploded perspective view showing a circuit board forming a video signal processing circuit according to an embodiment of the invention;

FIG. 3 is a perspective of an external view of a heat sink provided in a circuit board according to an embodiment of the invention;

FIG. 4 is a sectional view for explaining a mounting structure of a heat sink according to an embodiment of the invention;

FIG. 5 is a sectional view showing a modification of a radiating fin of a heat sink according to an embodiment of the invention;

FIG. 6 is a sectional view showing a modification of a radiating fin provided with a branch fin, according to an embodiment of the invention; and

FIG. 7 is a sectional view showing a modification of a branch fin according to an embodiment of the invention.

### DETAILED DESCRIPTION

Various embodiments according to the invention will be described hereinafter with reference to the accompanying drawings. In general, according to one embodiment of the invention, an electronic apparatus has a signal receiver to receive a signal, a circuit component to process a received signal, a circuit board provided with the circuit component, and a heat sink secure to the circuit component. The heat sink has a bottom part firmly contacting the plane of the circuit component remote from the circuit board, an upright part extended in the direction remote from the circuit board and set up on the bottom part, a radiating plate continued from the end of the upright part remote from the bottom part and extended substantially parallel to the circuit board, and a radiating fin extended from the radiating plate to the circuit board. The radiating fin is extended to the position remote from the circuit board by at least a mounting space, to ensure space to mount other circuit components between the radiating plate and circuit board. Or, the distance between specific adjacent radiating fins is set to the size to contain a circuit component.

Therefore, other circuit components can be arranged under the radiating plate while keeping the radiating effect by the radiating fins, and the size of an electronic apparatus can be reduced.

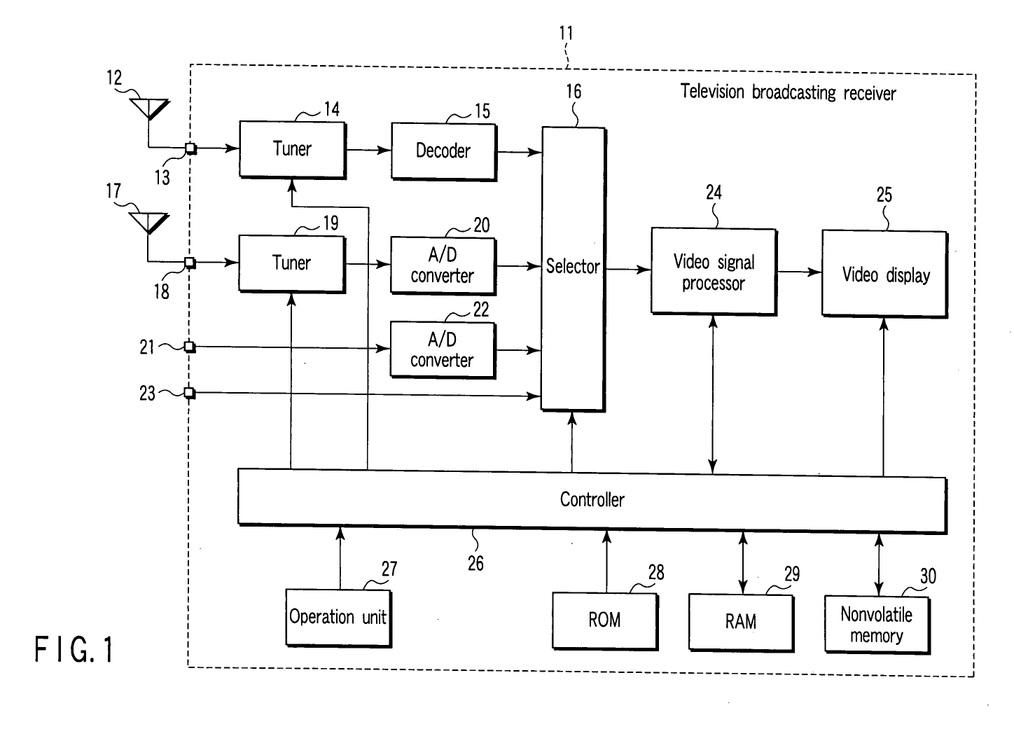

FIG. 1 schematically shows a video signal processing circuit of a television broadcasting receiver 11 as an electronic apparatus according to an embodiment of the invention.

A digital television broadcasting signal is received by an antenna 12 (signal receiving part) for receiving digital television broadcasting, and supplied to a tuner 14 through an input terminal 13. The tuner 14 selects and demodulates a signal of a desired channel of digital television broadcasting. The signal selected by the tuner 14 is supplied to a decoder 15, subjected to MPEG (Moving Picture Experts Group) 2 decoding, and output to a selector 16.

Contrarily, an analog television broadcasting signal is received by an antenna for receiving analog television broadcasting, and supplied to a tuner 19 through an input terminal 18. The tuner 19 selects and demodulates a signal of a desired channel of analog television broadcasting. The signal selected by the tuner 19 is supplied to an A/D (Analog/Digital) converter 20, converted to a digital signal, and decoding, and output to a selector 16.

An analog video signal supplied to an external input terminal 21 for an analog video signal is supplied to an A/D converter 22, converted to a digital signal, and output to the selector 16. A digital video signal supplied to an external input terminal 23 for a digital video signal is supplied directly to the selector 16.

The selector 16 selects one of four kinds of input digital video signals, and supplies it to a video signal processor 24. The video signal processor 24 processes the input digital video signal, and supplies it to a video display 15. As the video display 25, a flat panel display composed of a liquid crystal display or plasma display is used.

The television broadcasting receiver 11 integrally controls various operations including a receiving operation by the controller 26. The controller 26 is a microprocessor containing a CPU (Central Processing Unit), which receives operating information from a not shown operating unit 27 including a remote controller, and controls each component to reflect that operating information.

In this case, the controller 26 uses mainly a ROM (Read Only Memory) 28 storing a control program to be executed by the CPU, a RAM (Random Access Memory) 29 to supply a work area to the CPU, and a nonvolatile memory 30 to store various set information and control information.

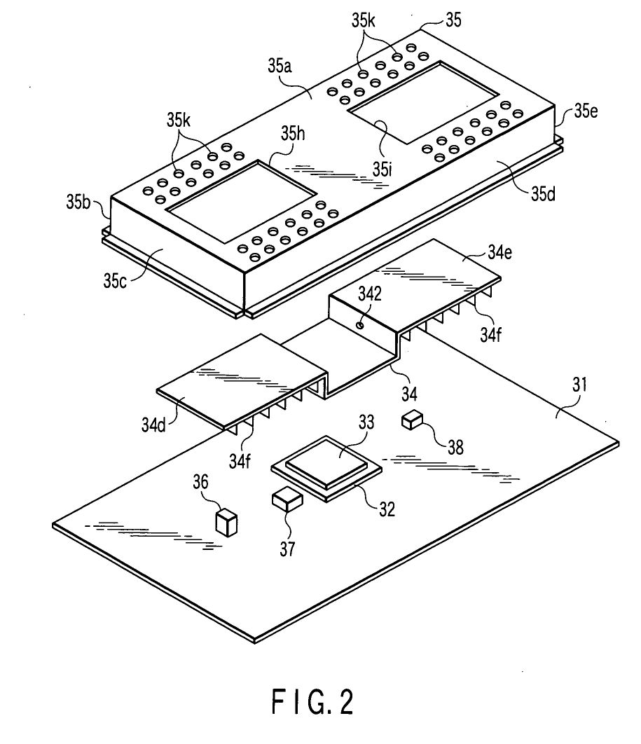

FIG. 2 shows a circuit board 31 forming a video signal processing circuit of the television broadcasting receiver 11. On the circuit board 31, circuit components and circuit patterns for forming a video signal processing circuit are mounted, though they are omitted in the drawing. Among the circuit components mounted on the circuit board 31, an LSI 32 composing the decoder 15 is heated relatively largely by the high-speed processing of digital data, and requires a heat-radiating measure.

For radiating the heat, a heat sink 34 is firmly contacting the side of the LSI 32 formed as a substantially square flat plate, opposite to the side faced to the circuit board 31, through a heat-conducting sheet 33 having flexibility. The LSI 32 mounted side of the circuit board 31 including the heat sink 34 is covered with a shield case 35, and the circuit components are electromagnetically shield.

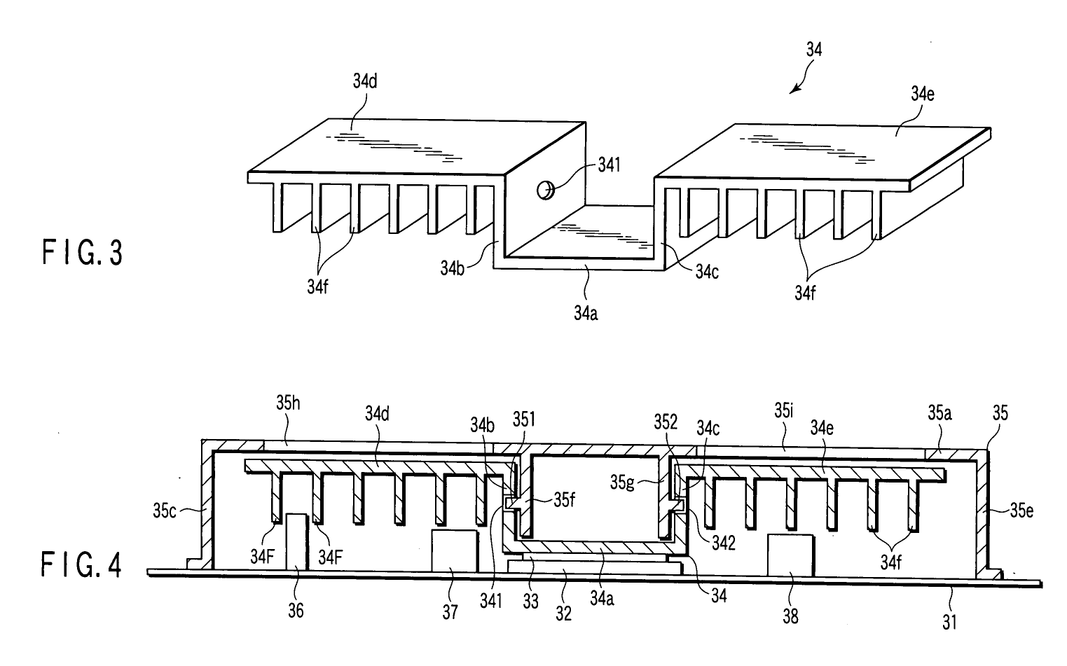

FIG. 3 is a perspective of an external view of the heat sink 34 according to an embodiment of the invention. FIG. 4 shows a mounting structure of the heat sink 34.

The heat sink 34 has a base plate 34a (bottom part), side plates 34b and 34c (upright part), radiating plates 34d and 34e, and radiating fins 34f (12 fins in this embodiment). The heat sink 34 is formed as one body by extruding metal material with heat conductivity. The base plate 34a is formed as a substantially square flat plate, and contacts the heat-conducting sheet 33 in the position parallel to the circuit board 31. The side plates 34b and 34c are extended from the opposite both ends of the base plate 34a to the direction vertical to the base plate 34a and remote from the circuit board 31 in the same direction. The radiating plates 34d and 34e are extended outward from the ends of the side plates 34b and 34c in the direction parallel to the base plate 34a. Radiating fins 34f are extended toward the circuit board 31 from the lower side of the radiating plates 34d and 34e.

A pair of side plates 34b and 34c of the heat sink 34 has engaging holes 341 and 342 at the positions opposite to each other. The radiating plates 34d and 34e have the sizes (surface area) previously designed to obtain sufficient radiating effect for the LSI 32.

The shield case 35 is formed by pressing metal material as one body with a flat plate 35a formed like a substantially square plate, four side plates 35b, 35c, 35d and 35e extended from the peripheral edges of the plate 35a to the direction vertical to the flat plate 35a in the same direction toward a wiring board 31, and two fixed plates 35f and 35g projected from substantially the center of the flat plate 35a just like opposing to the side plates 34b and 34c of the heat sink 34.

The shield case 35 is secured to the circuit board 31 by contacting the open end portion formed by the side plates 35b-35e, covering the circuit components 32, 36, 37 and 38 mounted on the circuit board 31.

The fixing plates 35f and 35g of the shield case 35 have projections 351 and 352 to be fit in the engaging holes 341 and 342 of the side plates 34b and 34c of the heat sink 34.

Therefore, the heat sink 34 can be made as one body with the shield case 35 by fitting projections 351 and 352 of the fixing plates 35f and 35g of the shield case 35 in the engaging holes 341 and 342 of the side plates 34b and 34c of the heat sink 34. By securing the shield case 35 to the circuit board 31 in this state, the base plate 34a of the heat sink 34 is firmly contacting the heat-conducting sheet 33 with a pressure, completing the heat-radiating structure.

When the shield case 35 is secured to the circuit board 31 as described above, the radiating plates 34d and 34e of the heat sink 34 are opposite close to the flat plate 35a of the shield case 35. The flat plate 35a of the shield case 35 has through holes 35h and 35i, which are almost flogged by the radiating plates 34d and 34e, in the part opposite to the radiating plates 34d and 34e. Therefore, the radiating plates 34d and 34e are exposed to the outside of the shield case 35 through the through holes 35h and 34i, increasing the radiating effect.

As described above, according to the above-mentioned embodiment, the heat sink 34 and shield case 35 are made as one body, and the heat sink 34 is firmly contacting the heat-conducting sheet 33 when the shield case 35 is secured to the circuit board 31. It becomes unnecessary to press the heat sink 34 to the LSI 32 by using a leaf spring or a coil spring, and sufficient radiating effect can be obtained with a simple structure.

The through holes 35h and 35i almost clogged by the radiating plates 34d and 34e of the heat sink 34 are formed in the flat plate 35a of the shield case 35, and the radiating plates 34d and 34e are exposed to the outside of the shield case 35. The radiating effect can be increased with the simple structure, without decreasing the shielding effect.

Further, the projections 351 and 352 of the fixing plates 35f and 35g projecting vertical from the flat plate 35a of the shield case 35 are fit in the engaging holes 341 and 342 of the side plates 34b and 34c of the heat sink 34. A member to secure the heat sink 34 to the shield case 35 is not projected outward from the flat plate 35a of the shield case 35. This also contributes the simplified structure and reduced size.

In the above-mentioned embodiment, the engaging holes 341 and 342 are formed in the side plates 34b and 34c of the heat sink 34, and the projections 351 and 352 are formed in the fixing plates 35f and 35g of the shield case 35. But, the structure is not limited to this. Projections may be formed in the side plates 34b and 34c of the heat sink 34, and engaging holes may be formed in the fixing plates 35f and 35g of the shield case 35.

The engaging holes 341 and 342 may not be holes penetrating the side plates 34b and 34c, and may be cavities to fit the projections 351 and 352.

The heat sink 34 of this embodiment has the radiating fins 34f extended substantially parallel to each other from the radiating plates 34d and 34e toward the circuit board 31. All the radiating fins 34f are made short, so that the ends of the radiating fins 34f (lower ends in the drawing) remote from the radiating plates 34d and 34e do not come close to the circuit board 31. Namely, to ensure space to mount the LSI 32 (circuit component) with the heat sink 34 and other circuit components 37 and 38 on the circuit board 31, the ends of the radiating fins 34f are extended from at least the upper surface of the circuit board 31 to the position to ensure the mounting space. In this embodiment, the heights of the circuit components 37 and 38 from the circuit board 31 are higher than the height of LSI 32, and the radiating fins 34f are extended to the position remote from the circuit board 31, exceeding the height of the LSI 32.

As described above, by making the radiating fins 34f extending to the circuit board 31 short, other circuit components 37 and 38 can be mounted in the space between the circuit board 31 and heating plates 34d and 34e of the heat sink 34, and the mounting space of the components 37 and 38 can be ensured while keeping the radiating effect of the heat sink 34. Therefore, the size of the circuit board 31 can be reduced, and the television broadcasting receiver 11 can be made compact.

Among the radiating fins 34f of the heat sink 34 of this embodiment, specific adjacent radiating fins 34F are separated by the degree to contain another circuit component 36 mounted on the circuit board 31 in the space therebetween. In other words, to place the relatively high circuit component 36 under the radiating fins 34d and 34e, set the interval of the radiating fins 34F appropriately to meet the width of the circuit component 36, and place the circuit component 36 between the radiating fins.

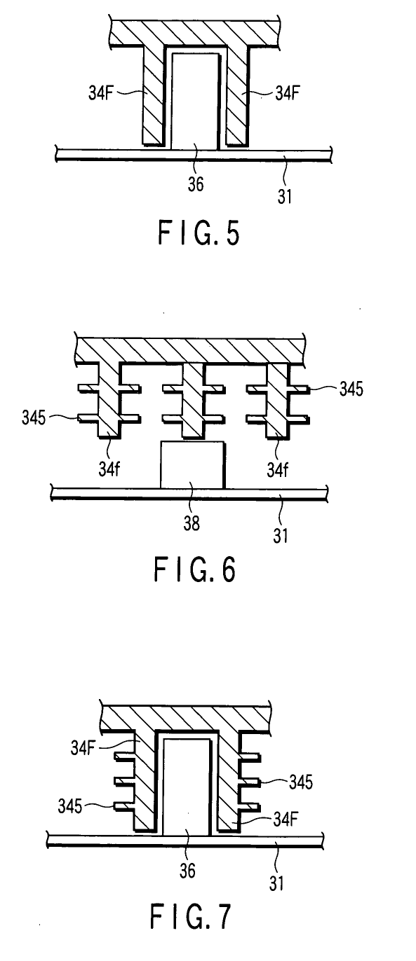

These specific radiating fins 34F are unnecessary to be made short like the radiating fins 34f, and can be extended to the position close to the circuit board 31, as shown in FIG. 5. This increases the radiating effect a little more. Similarly, the radiating fins 34f placed at the positions not interfering with the circuit components 36, 37 and 38 are unnecessary to be made short, and better to be extend to the position close to the circuit board 31.

As described above, the mounting space of another circuit component 36 can be ensured between the circuit board 31 and radiating plates 34d and 34e, also by setting the interval of the radiating fins 34F so as to place the circuit component 36 between the adjacent radiating fins 34F. Therefore, the size of the circuit board 31 can be reduced while keeping the radiating effect of the heat sink 34, and the television broadcasting receiver 11 can be made compact. In this case, the heat of the heat sink 34 may be transmitted to the circuit component 36 through the radiating fins 34F, and it is desirable to use a heat-insulating material between the circuit component 36 and radiating fins 34F.

Further, in order to increase the radiating effect of the heat sink 34, each of the radiating fins 34f may have branch fins 345 extending in the direction crossing the extending direction of the fins 34f, as shown in FIG. 6 and FIG. 7. Particularly, as shown in FIG. 7, when providing the branch fins 345 in the radiating fins 34F containing the circuit component 36 in the space to the adjacent radiating fins 34F, the branch fins 345 may be extended in the direction remote from the circuit component 36.

The number of the radiating fins 34f and branch fins 345 can be optionally set. As the number of the fins is increased, the radiating effect is increased. However, even one radiating fin 34f or 345 can increase the radiating effect. Particularly, when the direction of air current for the heat sink 34 is along the fin, it is effective to provide the branch fins 345.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the heat sink 34 of the above-mentioned embodiment, two radiating plates 34d and 34e are extended from both ends of the base plate 34a to the opposite direction through the side plates 34b and 34c. The heat sink structure is not limited to this. The shape of the radiating plate can be optionally changed. The radiating plates are desirably shaped close to a square, so that they are remote from the heat source LSI 32 by the equal distance. The radiating fins 34f of this embodiment can be provided irrespectively of the position of the heat sink even if there is a circuit component between the radiating plate and circuit board, and square radiating plates can be used.

What is claimed is:

1. An electronic apparatus comprising:
a signal receiver which receives a signal;
a circuit component which processes a received signal;
a circuit board on which the circuit component is mounted; and
a heat sink which is secured to the circuit component,
wherein the heat sink has a bottom part firmly contacting the plane of the circuit component remote from the circuit board, an upright part extended in the direction remote from the circuit board and set up on the bottom part, a radiating plate continued from the end of the upright part remote from the bottom part and extended substantially parallel to the circuit board, and at least one radiating fin extended from the radiating plate to the circuit board, and
the radiating fin is extended to the position remote from the circuit board by at least a mounting space, to ensure space to mount other circuit components between the radiating plate and circuit board.

2. The electronic apparatus according to claim 1, wherein the heat sink has radiating fins extended substantially parallel to each other from the radiating plate to the circuit board, and the distance between specific adjacent fins among the radiating fins is set to the size to contain another circuit component mounted on the circuit board.

3. The electronic apparatus according to claim 2, wherein the specific radiating fins are extended to the position close to the circuit board.

4. The electronic apparatus according to claim 1, wherein the radiating fin has at least one branch fin extended in the direction crossing the extending direction of the radiating fin.

5. An electronic apparatus comprising:
a signal receiver which receives a signal;
a circuit component which processes a received signal;
a circuit board on which the circuit component is mounted; and
a heat sink which is secured to the circuit component,
wherein the heat sink has a bottom part firmly contacting the plane of the circuit component remote from the circuit board, an upright part extended in the direction remote from the circuit board and set up on the bottom part, a radiating plate continued from the end of the upright part remote from the bottom part and extended substantially parallel to the circuit board, and radiating fins extended substantially parallel to each other from the radiating plate to the circuit board, and
the distance between specific adjacent fins among the radiating fins is set to the size to contain another circuit component mounted on the circuit board.

6. The electronic apparatus according to claim 5, wherein the radiating fins have at least one branch fin extended in the direction crossing the extending direction of the radiating fin.

7. The electronic apparatus according to claim 5, wherein among the radiating fins, other radiating fins not containing another circuit component between adjacent radiating fins are extended to the position remote from the circuit board by at least a mounting space, to ensure space to mount other circuit components between the radiating plate and circuit board.

8. The electronic apparatus according to claim 7, wherein the other radiating fins have at least one branch fin extended in the direction crossing the extending direction of the radiating fin.

9. A heat sink comprising:
a bottom part firmly contacting the plane of the circuit component remote from the circuit board;
an upright part extended in the direction remote from the circuit board and set up on the bottom part;
a radiating plate continued from the end of the upright part remote from the bottom part and extended substantially parallel to the circuit board, and
at least one radiating fin extended from the radiating plate to the circuit board,
wherein the radiating fin is extended to the position remote from the circuit board by at least a mounting space, to ensure space to mount other circuit components between the radiating plate and circuit board.

10. The heat sink according to claim 9, wherein the radiating fin is extended to the position remote from the circuit board, exceeding the height of the circuit component from the circuit board.

11. The heat sink according to claim 9, wherein the radiating fin has at least one branch fin extended in the direction crossing the extending direction of the radiating fin.

12. The heat sink according to claim 9, further comprising radiating fins extended substantially parallel to each other from the radiating plate to the circuit board, wherein
the distance between specific adjacent fins among the radiating fins is set to the size to contain another circuit component mounted on the circuit board.
